(19) United States
(12) Patent Application Publication
(10) Pub. No.: US 2024/0293811 A1
(43) Pub. Date: Sep. 5, 2024

(54) FLEX FOIL, MICRO-FLUIDIC CARTRIDGE AND MICRO-FLUIDIC ASSEMBLY

(71) Applicant: ams International AG, Jona (CH)

(72) Inventors: Erik Jan LOUS, Veldhoven (NL); Boon Chong CHEAH, Geldrop (NL)

(21) Appl. No.: 18/576,517

(22) PCT Filed: May 18, 2022
(86) PCT No.: PCT/EP2022/063423

§ 371 Date: Jan. 4, 2024

(30) Foreign Application Priority Data
Jul. 8, 2021 (DE) 10 2021 117 680.8

(51) Int. Cl. B01L 3/00

(52) U.S. Cl. CPC B01L 3/502715; B01L 2200/027; B01L 2200/04; B01L 2300/023; B01L 2300/0636; B01L 2300/0816; B01L 2300/168

(57) ABSTRACT

A flex foil for sealing a micro-fluidic cartridge includes a flexible carrier film and an integrated photodetector circuit including at least one photodetector. The carrier film includes at least one optically transparent window. The integrated photodetector circuit is arranged on the carrier film, such that the photodetector is aligned with the optically transparent window. The integrated photodetector circuit is electrically and operatively connected to the flexible carrier film.

### FIELD OF DISCLOSURE

The present disclosure relates to a flex foil for sealing a micro-fluidic cartridge, a micro-fluidic cartridge for a micro-fluidic assembly and to a micro-fluidic assembly, e.g. including a reader device to read out the micro-fluidic cartridge.

### BACKGROUND

Design of micro-fluidic cartridges plays a key role in the successful development of a diagnostic systems where ease of use, throughput, and cost per test are critical factors. This is particularly true for Point of Care Testing (or POCT for short) applications in which the cartridge also acts as an easy and intuitive user hardware interface and where optical detection is used to readout the micro-fluidic cartridge.

At low signal intensities, like for photon counting, as used in the most sensitive bio-diagnostic reactions, a close vicinity integration may be important as light intensities drops of with 1/R², where R is the distance between a sample in a micro-fluidic cartridge and a detector. It is common in the art, however, to rely on an integration with loose, large scale components, e.g. with diodes or ASICs at a distance from each other, with optical components (lenses, optical filters, . . . ) in between, such that the cartridge can be removed. Sometimes, ASICs are placed on a side of the micro-fluidic cartridge, where metal traces are also present.

At least for the followings reasons it may be important to keep R as small as possible. 1) Signal loss, caused by large (>detector diameter) distance between sample and detector. Even when there is optics in between. 2) Because of optics and/or sensor size, unable to miniaturize the detection part. This is needed for cost down and bring it into the field of Point-of-Care Testing. 3) In case of multi-parameter detection on the micro-fluidic cartridge, for which multiple sensors are needed, alignment and yield problems at each placement of the detector. For example, if each assembly yields 95% then at 16 sensors, the assembly yield becomes (0.95) 16=0.44. And 4) in case of multi-parameter detection with one sensor-ASIC, to minimize cross talk between the different sensors on the ASIC. More often a PCB and a separate detection system is used with additional optics and photo diodes or (for photon counting) photo multipliers are used.

It is an object of the present disclosure to provide a micro-fluidic system, which allows for a miniaturized cost-effective package and improved detection.

These objects are achieved by the subject-matter of the independent claims. Further developments and embodiments are described in the dependent claims.

It is to be understood that any feature described in relation to any one embodiment may be used alone, or in combination with other features described herein, and may also be used in combination with one or more features of any other of the embodiments, or any combination of any other of the embodiments unless described as an alternative. Furthermore, equivalents and modifications not described below may also be employed without departing from the scope of the flex foil for sealing a micro-fluidic cartridge, micro-fluidic cartridge for a micro-fluidic assembly and micro-fluidic assembly which are defined in the accompanying claims.

### SUMMARY

The following relates to an improved concept in the field of micro-fluidics. One aspect relates to use of a single flex foil to electrically wire and contact an integrated photodetector circuit (or ASIC) and closing the detection chambers of the microfluidic cartridge. Further aspects relate to closing the micro-fluidic cartridge and sensing wells (detection chambers). And having optically transparent windows at the sensing well locations. The flex foil comprises electrical conducting wiring and provides means to mount integrated circuits, such as the integrated photodetector circuit, to the electrically conducting wiring and/or pads. The flex foil may have contact points for a readout socket.

In at least one embodiment a flex foil for sealing a micro-fluidic cartridge comprises a flexible carrier film and an integrated photodetector circuit. The integrated photodetector circuit comprises at least one photodetector. The carrier film comprises at least one optically transparent window or cut out. The integrated photodetector circuit is arranged on the carrier film such that the photodetector is aligned with the optically transparent window. Finally, the integrated photodetector circuit is electrically and operatively connected to the flexible carrier film.

The term “carrier film” denotes a body of the flex foil, which comprises a flexible material such as a foil or film, for example. The carrier film may be complemented with electrical wiring to form the flex foil. Furthermore, components such as the integrated photodetector circuit can be electrically and operatively connected to the flexible carrier film to form the flexible foil.

The use of single flex foil to electrically wire and contact integrated circuits as well as closing the micro-fluidic cartridge gives a number of benefits. A minimum distance between a liquid sample in detection chambers and photodetectors can be achieved. The use of flex foil may void the need of an additional closing film, i.e. at least one film thickness less. In other words, the flex foil may act as a closing film, with the carrier film sealing off a micro-fluidic cartridge, for example. Furthermore, the flex foil enables multiple channel detection with a single integrated photodetector circuit placement which translates into low assembly cost, high yield, with less optical cross talk. Minimized cross talk between channels is possible through thinner film and smaller R and the use of opaque materials. Assembly is simplified due to minimized assembly steps (e.g., one film less). The resulting micro-fluidic assembly may be more light tight. Integration of integrated circuits, such as detector ASIC and other ASICs, on the same flex foil as well as contacts like SD-card contacts. A channel can be considered a separate detection well in micro-fluidics to be sensed, e.g. by an optical (sense SPAD array) sensor, covering one bio-diagnostics parameter.

In at least one embodiment the carrier film comprises an array of optically transparent windows. The integrated photodetector circuit comprises an array of photodetectors. The integrated photodetector circuit is arranged on the carrier such that each photodetector is aligned with a respective optically transparent window.

During operation a light signal originating from liquid in the detection chambers may only be detected via the optically transparent windows. Crosstalk may be reduced.

In at least one embodiment the carrier film comprises optically transparent and optically opaque material. The carrier film is patterned such that section of the carrier film comprising the optically transparent material form the one or more optically transparent windows. In addition, or alternatively, sections of the carrier film have cut-outs. The patterning provides a means to reduce crosstalk further. In fact, using the patterned sections may eliminate the need of additional optical barriers, which would else add an additional thickness. Ultimately, signal-to-noise ration may be improved.

In at least one embodiment the carrier film comprises at least one layer of the optically transparent material and at least one layer of the optically opaque material. The carrier film is patterned such that sections of the layers form the one or more optically transparent window. These layers provide a high degree of freedom to create patterns which effectively reduce crosstalk.

In at least one embodiment the flex foil further comprises an integrated driver circuit. The integrated driver circuit is arranged on the carrier film. Furthermore, the integrated driver circuit is electrically and operatively connected to the flexible carrier film. During operation, the integrated driver circuit controls the micro-fluidic cartridge and/or the integrated photodetector circuit.

In at least one embodiment the flex foil further comprises electrically conducting wiring and an interface. The wiring is operable to electrically access the integrated photodetector circuit and/or the integrated driver circuit via the interface. The wiring may primarily be used to electrically contact and operate the integrated circuits of the flex foil. However, the wiring may also be used as a heating element to set, control or keep constant a temperature or elevated temperature in the detection chambers.

In at least one embodiment the carrier film comprises one or more glue joints to contact the carrier film to the integrated photodetector circuit and/or the integrated driver circuit. At the same time the glue joints can be used to reduce the optical cross-talk between the photodetectors on the integrated photodetector circuit. Alternatively, the integrated photodetector circuit and/or the integrated driver circuit are embedded in the carrier film. In another alternative, a structured spacer structure is used to contact the carrier film to the integrated photodetector circuit and/or the integrated driver circuit and to reduce optical cross-talk between the photodetectors on the integrated photodetector circuit.

In at least one embodiment the carrier film has a thickness between 10 to 200 μm. This way a distance between photodetectors to a cartridge can be low.

In at least one embodiment a micro-fluidic cartridge for a micro-fluidic assembly comprises a cartridge body. The cartridge body has at least one detection chamber which is connected to a micro-channel to receive a liquid to be tested.

During operation the micro-fluidic cartridge receives the liquid to be tested, e.g. via the micro-channel. The liquid may be applied to the detection chamber via the connected micro-channel. The photodetector may detect a light signal, such as fluorescence or chemo-luminescence, from the liquid to be tested which is present in the detection chamber.

In at least one embodiment the cartridge body comprises multiple detection chambers which are connected to a respective micro-channel to receive one or more liquids to be tested. Each photodetector on the integrated photodetector circuit can be placed and aligned directly opposite to a detection chamber on the micro-fluidic cartridge.

The micro-fluidic cartridge can be considered a multiple channel cartridge which allows to test and receive not only a single liquid, but either a higher amount of one liquid or several different liquids to be tested. Due to the alignment of the photodetectors with respective detection chambers, the photodetectors may operate in parallel to record light signals such as fluorescence or luminescence from the respective liquids. The micro-fluidic cartridge may have detection chambers in different levels to allow for even further liquids to be tested in parallel.

In at least one embodiment the cartridge body comprises an optically opaque and/or non-reflective material. These materials help to reduce crosstalk.

In at least one embodiment the detection chamber and/or micro-channels are designed in the cartridge body as open cavities. These cavities can be closed and sealed by means of a closing film, such as the flex foil discussed above. In other words, the closing film may be used to seal the the detection chamber (s) and/or micro-channels instead of, or in addition to, the flex foil. For example, the closing film may have corresponding sections, optical windows and/or cut-outs, which correspond to thos of the flex foil, and vice versa. This way, the closing film and/or flex foil may align with the dections chambers and photodetectors in a same way.

The micro-fluidic cartridge can be used as a single (disposable) component, with electronic components arranged on the flex foil or any other suitable carrier. However, the micro-fluidic cartridge may also be implemented with the electronic components arranged on the flex foil, as discussed above. This way, the micro-fluidic cartridge may be disposable together with the flex foil.

For example, the micro-fluidic cartridge sealed with the closing film can be slid into a reader device over the electronic flex foil comprising the integrated photodetector circuit and/or integrated control circuit, in such a way that the detection chambers and the corresponding photodetectors are aligned. This allows close proximity of and use of optical barriers to prevent optical cross-talk between the pairs of detection chambers and photodetectors.

In at least one embodiment a micro-fluidic assembly comprises a closing film, which is attached on the micro-fluidic cartridge so as to seal detection chambers and/or micro-channels. Furthermore, the micro-fluidic assembly also comprises a microfluidic cartridge according to one or more of the aspects discussed above. The micro-fluidic cartridge is arranged on the closing film such that one or more of the photodetectors of the integrated photodetector circuit are aligned with a respective detection chamber. The micro-fluidic cartridge can extend larger than only the area used for the detection chambers.

In at least one embodiment, the micro-fluidic assembly comprises a flex foil according to one of the aspects discussed above, which is attached on the micro-fluidic cartridge in addition to the closing film. Alternatively, the closing film comprises the flex foil, i.e. acts as or replaces the closing film, so as to seal the detection chambers and/or micro-channels.

In at least one embodiment the micro-fluidic assembly comprises a reader device. The reader device further comprises an opening to insert the micro-fluidic cartridge into a measurement position in order to conduct a fluorescence and/or chemoluminescence measurement.

The micro-fluidic measuring device can be implemented to conduct a fluorescence based measurement or a chemo-luminescence based measurement. For the first type of measurement, the reader may be equipped with an excitation light source to illuminate the one or more detection chambers and/or a processing unit to control the light source. This way, the photodetectors may record fluorescence returning from the liquid in the detection chambers. In such case the photodetectors are equipped with the required optical filter arrangement to block the excitation light wavelength and detect the fluorescent wavelength.

For the second type of measurement, the reader does not necessarily need to be equipped with a light source as no excitation may be needed to initiate luminescence. However, the micro-fluidic cartridge, i.e. micro-channels, can be used to insert chemical compounds to trigger chemical reactions, which yield a chemo-luminescent response. However, the liquids may already be present in a freeze-dried chemistry in the micro-fluidic detection chamber (or before in the microfluidic system/channels). Triggering may occur by adding a sample-liquid (e.g. urine, saliva, blood) from outside the cartridge, for example.

The processing unit may control and/or process the measurements. The reader device may be equipped to conduct one or both of the measurements discussed above.

Further aspects of this disclosure relate to the following. The integrated photodetector circuit, e.g. a photon counter detector ASIC, can be assembled close to detection chambers of a micro-fluidic cartridge. Sections of the cartridge and/or flex foil should be made from opaque material, e.g. in black, with optically transparent windows or, via cut-outs, in direct contact with a passivation layer of the integrated circuits.

The proposed concept allows for single to multiple channel detection with a single ASIC placement on the micro fluidic cartridge. This gives low assembly cost, high yield, less alignment problems and allows for minimized cross talk between channels. Some measures proposed herein are: a) minimal film thicknesses used: from 200 μm down to ˜10 μm; b) black coatings or paints and/or black glues and/or black molds can be used; c) non-reflective (black) coatings or paints can be used; d) photopic and pigmented films

The proposed concept allows to minimize a distance between sample and detector, which increases sensitivity. This is supported by film thicknesses used: from 200 μm down to ˜10 μm and the need for less layers to be used to decrease distance. Hence single layers become multifunctional. The proposed flex foil functions as closing microfluidic well, electrical wiring, electrical heating, heatsink integration, and/or cooling element integration.

However, the concept discussed herein can be implemented without flex foil, such as carriers like laminate or PCB, even with FAM packages.

Assembly steps can be fewer by using less components and fewer layers. Light tight assembly can be achieved enabling highly sensitive photon counting detection, e.g. all in black, etc. Some or all components can be disposable and be implemented with small form factor (like a SD-card, or smaller).

The flex foil and/or carrier allows to integrate a heat sink or cooler (like smallest Peltier element of 1 mm² may be sufficient to gain considerably in sensitivity). With flex foil an integrated electrical wiring for ASIC, integrated heater can be combined with closing of the micro-fluidic cartridge.

The following description of figures of example embodiments may further illustrate and explain aspects of the improved concept. Components and parts with the same structure and the same effect, respectively, appear with equivalent reference symbols. Insofar as components and parts correspond to one another in terms of their function in different figures, the description thereof is not necessarily repeated for each of the following figures.

### BRIEF DESCRIPTION OF THE DRAWINGS

In the Figures:

FIG. 1 shows an example embodiment of a micro-fluidic assembly,

FIG. 2 shows another example embodiment of a micro-fluidic assembly,

FIG. 3 shows another example embodiment of a micro-fluidic assembly,

FIG. 4 shows an example embodiment of a micro-fluidic cartridge,

FIG. 5 shows another example embodiment of the flex foil of a micro-fluidic cartridge,

FIG. 6 shows another example embodiment of the flex foil of a micro-fluidic cartridge, and

FIG. 7 shows another example embodiment of the flex foil of a micro-fluidic cartridge, and

FIGS. 8A, 8B show example embodiments of a micro-fluidic measuring arrangement.

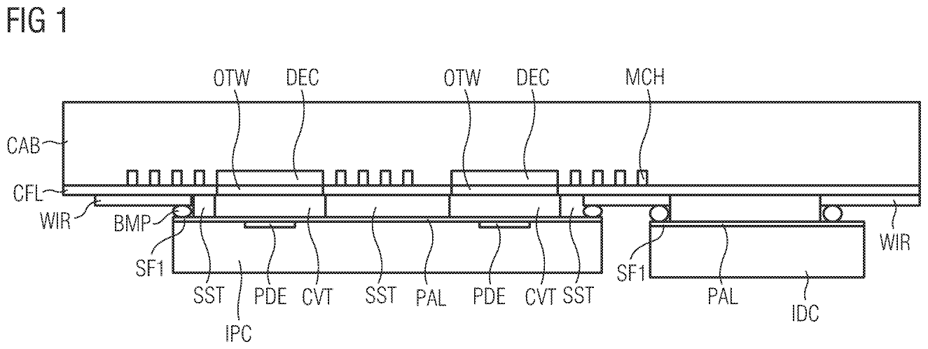

FIG. 1 shows an example embodiment of a micro-fluidic assembly. The assembly comprises a micro-fluidic cartridge and a flex foil.

The flex foil further comprises a carrier film CFL. For example, the carrier film is a plastic foil and has a thickness between 10 and 200 μm. Furthermore, the flex foil comprises electrically conducting wiring WIR, which is arranged on the carrier film. Alternatively, the wiring may also be embedded in the carrier film. The wiring may be connected to an interface (not shown), to electrically access the flex foil and its components via the interface to for instance a reader device.

The carrier film CFL is patterned into different sections. There are sections that comprise optically transparent material and form optically transparent windows OTW. Other sections have optically opaque material. In this embodiment, the carrier film is patterned from the inside. For example using photopic films or pigmented films, patterned or not. Alternatively, the carrier film can be patterned from the outside. For example, the carrier film comprises a layer of the optically transparent material. The optically opaque material has been applied in a patterned fashion on said layer, e.g. using black coating, paint, glue, mold or other non-reflective material. This pattern can be considered a patterned layer of optically opaque material. The sections which remain free of optically opaque material form the optically transparent windows OTW. Alternatively, the OTW can be made by cut-outs in the carrier film CFL.

An integrated photodetector circuit IPC and an integrated driver circuit IDC are arranged on and mounted to the carrier film CFL. Both the integrated photodetector circuit IPC and the integrated driver circuit IDC are electrically connected to the wiring by means of bumps BMP. This way, there is an electrical connection between the circuits and also, e.g. via the interface, to an external component. For example, during operation, the integrated driver circuit IDC controls the micro-fluidic cartridge and/or the integrated photodetector circuit. Alternatively, the electrical connection between the wiring on the carrier film CFL and integrated circuits IPC and IDC can be made by anisotropic conducting tape or paste/glue.

The integrated photodetector circuit IPC is implemented as an ASIC with one or more photodetectors PDE integrated in a common integrated circuit. The number of photodetectors translates into a number of measurements which can be conducted in parallel. Typically, the photodetectors are photodiodes, such as single photon avalange photodiodes which provide highly sensitive (photon counting) detection.

In the drawing, the photodetectors PDE are represented as depletion zones of SPADs. These zones are arranged as active surfaces facing towards the micro-fluidic cartridge, opposite to each detection chamber DEC on the carrier film CFL. The integrated photodetector circuit IPC and, thus, the active surfaces are protected by means of a passivation layer PAL of the CMOS which is arranged on the integrated photodetector circuit, as well as the driver circuit. Furthermore, the bumps are arranged on the surface SF1 facing the micro-fluidic cartridge to allow for electrical contacting the integrated photodetector circuit to the wiring WIR. Furthermore, a spacer structure SST, e.g. comprising a mold or glue, is arranged on the surface SF1. By means of this spacer structure the flex foil is at a distance to the surface SF1 of both integrated photodetector circuit IPC and driver circuit IDC. At the same time the spacer structure SST protects and closes a detection cavity CVT. The spacer structure also glues to the carrier film CFL and thereby attaches the integrated photodetector circuit IPC and driver circuit IDC to the flex foil. Finally, the spacer structure SST can be structured in a way to act as an optical barrier to minimize optical cross-talk between the different DEC-PDE pairs/sets. For example, the detection cavities CVT may be arranged in the spacer structure SST so that the photodetectors PDE are enclosed by the structure. This way optical crosstalk between the photodetectors can be reduced. Preferentially, the spacer structure is made from opaque materials.

The micro-fluidic cartridge comprises one or more detection chambers DEC, which are arranged into a cartridge body CAB. The cartridge body may be a glass, plastic or mold of transparent or opaque mold material, or a combination of both. The micro-fluidic cartridge comprises a single detection chamber (single channel) to allow for a measurement at a time or a number of detection chambers (multiple channels) to allow for a number of measurements which can be conducted in parallel. In this case, the cartridge body CAB is made from opaque materials to reduce optical cross-talk.

The micro-fluidic cartridge further comprises a number of micro-channels MCH, which are also arranged into a cartridge body. The micro-channels connect the detection chambers in order to input a liquid to be tested. For example, there may be a dedicated micro-channel for each detection chamber in order to supply the detection chambers individually with a liquid to be tested. However, a number of detection chambers may also share a common micro-channel so that these are supplied with a same liquid to be tested. Or leading out to the same waste liquid chamber.

The micro-fluidic cartridge is arranged on the carrier film CFL, such that the photodetectors PDE are aligned with the optically transparent windows OTW. For example, the carrier film CFL rests on the spacer structure SST. In fact, the carrier film CFL is only connected to the spacer structure SST via its sections having the optically opaque material, effectively keeping open the sections of optically transparent material. This way, the detection cavities are also aligned with the optically transparent windows OTW and detection chambers DEC of the micro-fluidic cartridge. At the same time there is a dedicated photodetector PDE from the integrated photodetector circuit IPC aligned with a respective detection chamber DEC.

The flex foil has two functions simultaneously. First, it provides electrical wiring patterns for electrically contacting the integrated photodetector circuit IPC and the integrated driver circuit IDC. Second, the micro-fluidic cartridge, i.e. the detection chambers DEC and/or micro-channels MCH are sealed from the environment by means of the flex foil rather than an additional closing film. This way, the photodetectors are not in direct contact with the liquid to be tested. In addition, there is no extra space needed as no closing film is necessary. This ensures a shorter detection chamber to photodetector distance. Due to the 1/R² dependency signal-to-noise ration can be increased.

As an option, the flex foil may use the wiring WIR (or an additional wiring) for heating the detection chambers. This way, the wiring may act as a heating element. There may also be other heating elements integrated into the flex foil such as thermos elements. In fact, such heating elements in the flex foil can be arranged to be in thermal contact with a single detection chamber DEC (single channel) or with a number of detection chambers (multiple channels). Due to the thermal contact the heating element may conduct heat to one or more of the detection chambers and may alter a temperature of a liquid to be tested, which may be present in the detection chambers. This way, the liquid in a detection chamber may be heated to a desired temperature, or a said temperature can be held constant for a duration of one or consecutive measurements in order to set a reference condition. For example, the liquid can be set to room temperature or 37° C. to mimic a body temperature. The heating element can be electrically connected to the integrated circuit and/or to a driver circuit.

In other embodiments the flex foil may comprise just a single layer of either optically transparent or optically opaque material. The patterning can be achieved inside or outside, as discussed above. However, in case the flex foil comprises a single layer of optically opaque material cutouts may pattern the flex foil into the sections to form the optically transparent windows. For example, the cutouts may define cavities which are aligned with the photodetectors and detection chambers.

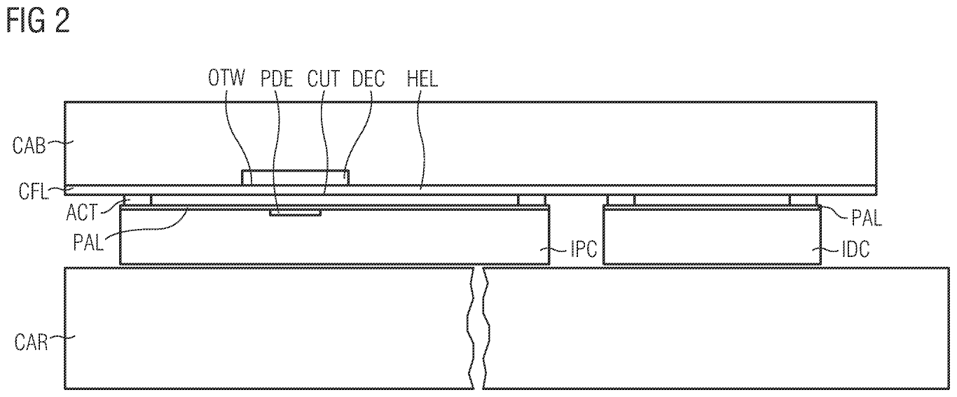

FIG. 2 shows another example embodiment of a micro-fluidic assembly. This embodiment is similar to the one shown in FIG. 1. In the following some aspects are highlighted, while others are not discussed in detail again, but may be present nonetheless.

In this embodiment the micro-fluidic cartridge comprises multiple detection chambers or a single detection chamber, as depicted, as well as single or multiple channels. A heating element HEL is arranged in a flex foil. For example, the heating element comprises a heating coil. The flex foil is arranged on the micro-fluidic cartridge, i.e. at a surface of the cartridge body (not shown). Furthermore, the flex foil is attached to the integrated photodetector circuit and driver circuit via an anisotropic conducting tape ACT. The foil is optically transparent or may comprise a number of cutouts CUT, which align with the photodetectors PDE. The integrated photodetector circuit IPC and the driver circuit IDC are mounted to a carrier CAR, which may be a polyimide laminate or PCB. This layer can also be replaced by a metal heat sink to isolate heat from the integrated circuits.

The flex foil may comprise a single layer of optically opaque material with cutouts to form the windows OTW. For example, the cutouts may define cavities which are aligned with the photodetectors and detection chambers.

However, the flex foil may be double sided with different functionality. For example, a heating element, such as wiring or coil, is arranged on (or embedded in) one side for heating. And on the other side the wiring for electrically contacting the integrated circuits is arranged on (or embedded in) the other side. Despite this twofold functionality the flex foil still saves foil thickness, e.g. as compared to an additional closing film.

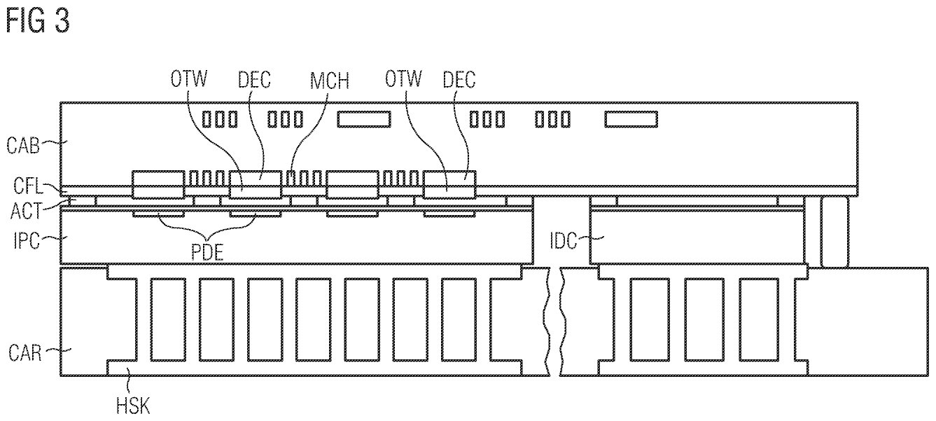

FIG. 3 shows another example embodiment of a micro-fluidic assembly. This embodiment is similar to the one shown in FIG. 1 or 2. In the following some aspects are highlighted, while others are not discussed in detail again, but may be present nonetheless.

This embodiment can be considered a combination of those discussed above with respect to FIGS. 1 and 2. An additional thickness and assembly step can be saved by using anisotropic conducting tape ACT rather than the spacer structure SST. The flexible foil may, outside the windows OTW, be sufficiently opaque or black to eliminate crosstalk (e.g. dispense or silk screen printed or photopic film based). As an option, the foil may be double sided or layered to have a heater element. The integrated photodetector circuit IPC and the driver circuit IDC may, as an option, be mounted to a carrier CAR, which may be a polyimide laminate or PCB. This layer can also be replaced by a metal heat sink to isolate heat from the integrated circuits.

The use of a carrier supports the use also of a cooling element. The cooling element can, as an option, be arranged, in thermal contact, to the integrated photodetector circuit PC. For example, the cooling element can be mounted directly underneath the integrated photodetector circuit or a carrier. One option is to implement the cooling element by a Peltier element, with its cooling side mounted to the integrated photodetector circuit. In a lateral dimension the Peltier element is similar in size than the integrated photodetector circuit. Thus, a small Peltier element may suffice to cool all photodetectors in the integrated photodetector circuit. A heat sink further supports efficient heat transfer to and away from the integrated photodetector circuit. The heat sinks can be implemented as vias in the carrier, for example.

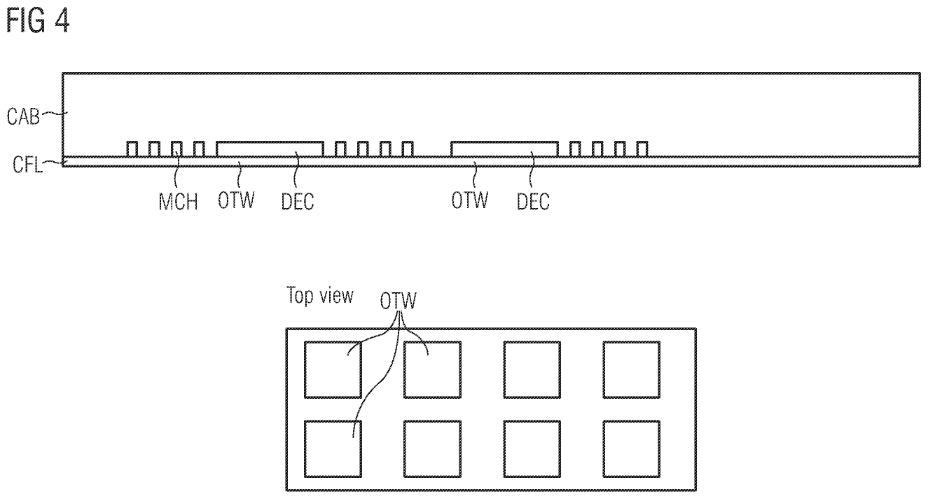

FIG. 4 shows an example embodiment of a micro-fluidic cartridge with a closing film. The drawing in the top depicts the micro-fluidic cartridge, i.e. not in its assembled state as shown in FIG. 1. The micro-fluidic cartridge is sealed with a closing film. The closing film can be the flex foil or a patterned closing film. The drawing at the bottom shows the micro-fluidic cartridge with closing film in a top view (from below if seen from the integrated photodetector circuit). It shows the optical transparent windows OTW, which either are cutouts in the carrier film CFL or a section of optically transparent material. The detection chambers (not shown) are arranged below the optical transparent windows OTW.

FIG. 5 shows an example embodiment of a patterned a closing film. The film comprises a single layer having a pattern of sections with optically transparent material and optically opaque material. The film comprises a layer of optically transparent material and can be patterned from the outside, e.g. one sided, both side or by injecting pigments or carbon. A photopic material can also be used to achieve the same anisotropy in optical density, laterally in the film versus perpendicular to the film.

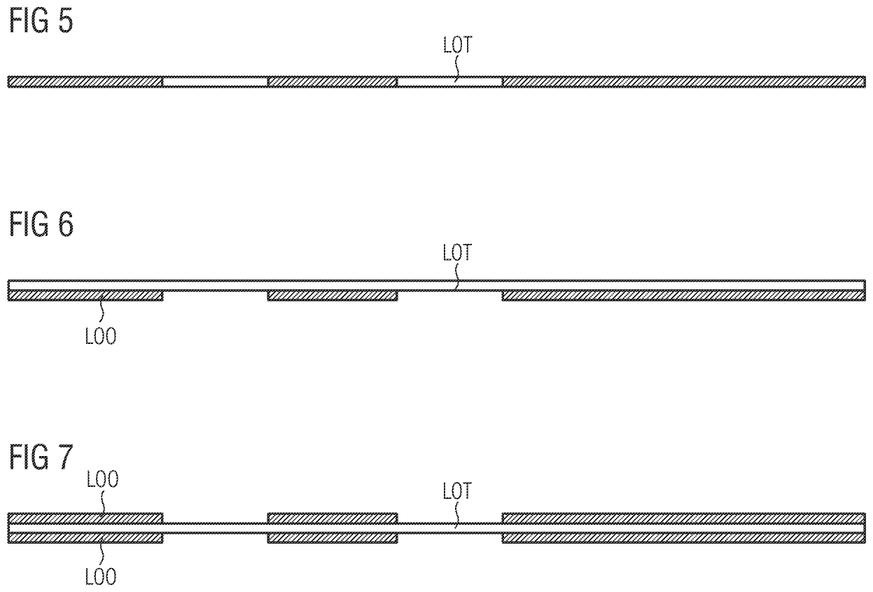

FIG. 6 shows another example embodiment of a patterned a closing film. The film comprises a layer LOT of optically transparent material and a layer LOO of optically opaque material stacked together. Alternatively, the layer LOO can also be constructed of, e.g. one sided, by black paint or glues.

FIG. 7 shows another example embodiment of a micro-fluidic cartridge. The film comprises a layer LOT of optically transparent material and two layers LOO of optically opaque material stacked together. Alternatively, the layer LOO can also be constructed of, e.g. both sided, by black paint or glues.

The films shown in FIGS. 4 to 7 can be patterned into black and clear parts. For example, the film is made through a thin film molding process or a black carbon doping process. The film can be patterned from the outside, e.g. one sided, both side or by black paint or glue.

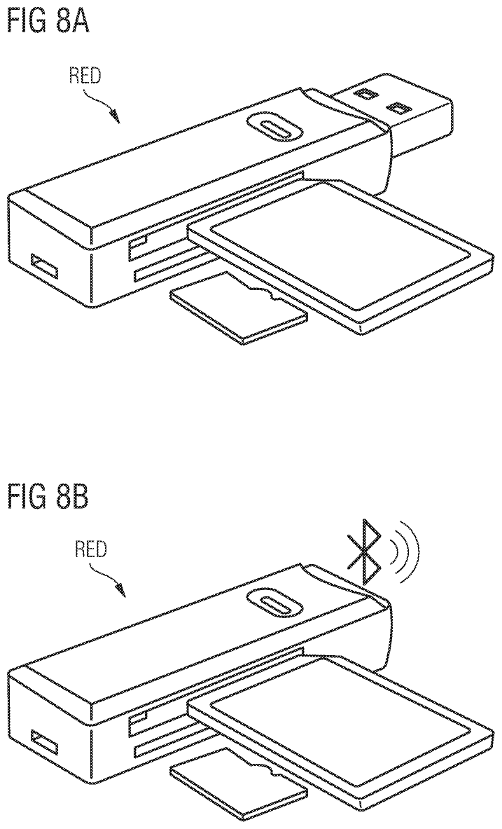

FIGS. 8A and 8B shows an example embodiment of a micro-fluidic measuring device. The device comprises a micro-fluidic cartridge as discussed in the previous Figures. Furthermore, the device comprises a reader device RED, which has an opening to insert the micro-fluidic cartridge into a measurement position.

The micro-fluidic measuring device can be implemented to conduct a fluorescence based measurement or a chemo-luminescence based measurement. For the first type of measurement, the reader may be equipped with an excitation light source to illuminate the one or more detection chambers and/or a processing unit to control the light source. This way, the photodetectors may record fluorescence returning from the liquid in the detection chambers. In such case the photodetectors are equipped with the required optical filter arrangement to block the excitation light wavelength and detect the fluorescent wavelength.

Chemo-luminescence is the emission of light (luminescence) as the result of a chemical reaction. For the second type of measurement, the reader does not need to be equipped with a light source as no excitation may be needed to initiate luminescence. However, the micro-fluidic cartridge, i.e. micro-channels, can be used to insert chemical compounds to trigger chemical reactions, like test fluids as urine, saliva, blood, or derivates thereof, which initiate and yield a chemo-luminescent response. This may be controlled and/or processed by the processing unit. The reader device may be equipped to conduct one or both of the measurements discussed above. The reader may be arranged with a USB interface (FIG. 8A) or a wireless network interface, such as Bluetooth (FIG. 8B).

While this specification contains many specifics, these should not be construed as limitations on the scope of the improved concept or of what may be claimed, but rather as descriptions of features specific to particular embodiments of the improved concept. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous.

A number of implementations have been described.

Nevertheless, various modifications may be made without departing from the spirit and scope of the improved concept. Accordingly, other implementations are within the scope of the claims.

The micro-fluidic cartridge can be used with a flex foil sealing the cartridge and connecting the integrated circuits. However, the cartridge can also be used with a closing film for sealing and the integrated circuits being arranged on a carrier.

In this context, further aspects relate to integration of an optical detection chip and a micro-fluidics cartridge, containing light emitting chemistry. Especially at low signal intensities, like for photon counts, as used in the most sensitive bio-diagnostic reactions, the close vicinity integration is important as light intensities drops of with 1/R², where R is the distance between the microfluidics* (=sample) and the detector.

Solutions include FAM, a film assisted molded package sensor chip in interface with the microfluidic cartridge or a flex foil bonded sensor chip, in interface with the microfluidic cartridge, or TSV, through silicon vias containing chips, in interface with the microfluidic cartridge. A micro-fluidic cartridge can be placed on top of an assembly opening of the sensor ASIC. A micro-fluidic cartridge can be placed in the assembly opening of the sensor ASIC. A micro-fluidic cartridge can be placed in the assembly opening of the sensor ASIC, such that the fluid is in direct contact with the sensor ASIC.

Integration of electric wiring and heater can be achieved in the flex foil, integrated circuits and/or carrier. Integration of a cooling element (Peltier, mems cooler) can be done as an option. A single flex foil can be used to electrically wire and contact (detector) integrated circuits as well as sealing the wells of the microfluidic cartridge.

The proposed concept enables simpler assembly, including single-Multiple channel detection with one ASIC placement (low assembly cost, high yield, less alignment problems), reduced cross talk between channels, reduced distance between sample and detector gives increased sensitivity, reduced assembly steps, light tight assembly enabling photon counting detection, integrated heat sink and/or cooler, and with flex foil: integrated electrical wiring for ASIC, integrated heater, closing of the cartridge.

### REFERENCES

ACT anisotropic conducting tape
BMP bump
CAB cartridge body
CAR carrier
CFL carrier film
CUT cutout
CVT detection cavity
DEC detection chamber
IDC integrated driver circuit
IPC integrated photodetector circuit
HSK heat sink
LOO layer of optically opaque material
LOT layer of optically transparent material
MCH micro-channel
OTW optically transparent windows
PAL passivation layer
PDE photodetector
RED reader device
SF1 surface
WIR electrically conducting wiring

1. A flex foil for sealing a micro-fluidic cartridge, comprising a flexible carrier film and an integrated photodetector circuit comprising at least one photodetector; wherein:
the carrier film comprises at least one optically transparent window,
the integrated photodetector circuit is arranged on the carrier film, such that the photodetector is aligned with the optically transparent window, and
the integrated photodetector circuit is electrically and operatively connected to the flexible carrier film.

2. The flex foil according to claim 1, wherein:
the carrier film comprises an array of optically transparent windows,
the integrated photodetector circuit comprises an array of photodetectors, and
the integrated photodetector circuit is arranged on the carrier film, such that each photodetector is aligned with a respective optically transparent window.

3. The flex foil according to claim 1, wherein:
the carrier film comprises optically transparent and optically opaque material, and
the carrier film is patterned, such that sections of the carrier film comprising the optically transparent material form the one or more the optically transparent windows, and/or that sections of the carrier film have cut-outs.

4. The flex foil according to claim 3, wherein:
the carrier film comprises at least one layer of the optically transparent material and at least one layer of the optically opaque material, and
the carrier film is patterned, such that sections of the layers form the one or more the optically transparent windows.

5. The flex foil according to claim 1, further comprising an integrated driver circuit, wherein:
the integrated driver circuit is arranged on the carrier film, and
the integrated driver circuit is electrically and operatively connected to the flexible carrier film.

6. The flex foil according to claim 1, further comprises electrically conducting wiring and an interface, wherein the wiring is operable to electrically access the integrated photodetector circuit and/or the integrated driver circuit via the interface.

7. The flex foil according to claim 1, wherein
the carrier film comprises one or more glue joints to contact the carrier film to the integrated photodetector circuit and/or the integrated driver circuit,
the carrier film comprises one or more structured spacer structure to contact the carrier film to the integrated photodetector circuit and/or the integrated driver circuit and/or to block optical cross talk between the photodetectors, or
the integrated photodetector circuit and/or the integrated driver circuit are embedded in the carrier film.

8. The flex foil according to claim 1, wherein the carrier film has a thickness between 10 to 200 μm.

9. A micro-fluidic cartridge for a micro-fluidic assembly, comprising a cartridge body having at least one detection chamber which connected to a micro-channel to receive a liquid to be tested.

10. The micro-fluidic cartridge according to claim 9, wherein cartridge body comprises multiple detection chambers which are connected to respective micro-channels to receive one or more liquids to be tested.

11. The micro-fluidic cartridge according to claim 9, wherein the cartridge body comprises an optically opaque and/or non-reflective material.

12. The micro-fluidic cartridge according to claim 9, wherein
the detection chambers and/or micro-channels are designed in the cartridge body as open cavities and/or
the detection chambers and/or micro-channels are sealed by means of closing film arranged on the cartridge body, in particular, sealed by means of the closing film instead of, or in addition to, the flex foil.

13. A micro-fluidic assembly, comprising:
a closing film attached on the micro-fluidic cartridge so as to seal detection chambers and/or micro-channels, and, and
a micro-fluidic cartridge according to claim 9, and wherein:
the micro-fluidic cartridge is arranged on the closing film such that one of more of the photodetectors of the integrated photodetector circuit is aligned to a respective detection chamber.

14. The micro-fluidic assembly according to claim 13, wherein:
a flex foil according to claim 1 is attached on the micro-fluidic cartridge in addition to the closing film; or wherein
the closing film comprises the flex foil according to claim 1.

15. The micro-fluidic assembly according to claim 13, further comprising a reader device, wherein the reader device comprises an opening to insert the micro-fluidic cartridge into a measurement position to conduct a fluorescence and/or chemoluminescence measurement.
